(19) United States
(12) Patent Application Publication
(10) Pub. No.: US 2005/0172181 A1
(43) Pub. Date: Aug. 4, 2005

(54) System and method for production testing of high speed communications receivers

(75) Inventor: Fakhralden A. Huliehel, Zefat (IL)

Correspondence Address: DR. MARK FRIEDMAN LTD.;C/o Bill Polkinghorn, Discovery Dispatch, 9003 Florin Way, Upper Marlboro, MD, 20772, US

(73) Assignee: MELLANOX TECHNOLOGIES LTD.

(21) Appl. No.: 10/758,197

(22) Filed: Jan. 16, 2004

(51) Int. Cl. G01R 1/00; G01R 31/28

(52) U.S. Cl. 714/724

(57) ABSTRACT

A method for testing a semiconductor device with a multi-gigabit communications receiver includes combining a data output from a high-speed communications transmitter with a perturbation signal generated by automatic test equipment. The combined signal data signal including jitter and low voltage swings is input to the communications receiver port under test. The automatic test equipment determines the bit error rate of the parallel data output from the receiver port under test. This test method is appropriate for semiconductor devices with multiple transceiver ports.

### FIELD AND BACKGROUND OF THE INVENTION

The present invention relates to production testing of high-speed communications receivers and, more particularly, to a system and method of inserting jitter into multi-gigabit per second receivers for production testing.

Fast computer communications technologies have been emerging that utilize serial point-to-point physical links with data rates well beyond 1 Gigabit/sec (Gbps). These communications technologies, including Infiniband™ (2.5 Gbps), fiber channel (3.2 Gbps), SONET and Gigabit Ethernet, are being adopted in many applications including communications between servers, back-bone communications and data storage. High volume production has begun of new semiconductor devices that enable these technologies. Each of the new multi-gigabit semiconductor devices includes multiple (e.g 32 or 96) serializer/deserializer ports. As part of the production testing of these semiconductor devices, the multiple serializer/deserializer ports require individual performance testing and qualification.

U.S. Pat. No. 5,835,501 describes a jitter test system for a clock and data recovery (CDR) unit. The system disclosed includes a data generating apparatus, an apparatus for clocking the data generating circuit with a jittered clock and an apparatus for detecting a bit error-rate of a data signal output from the CDR unit. The jitter insertion method is based on a phase locked loop frequency modulation system. The invention is implemented as a built-in self-test (BIST) circuit in the semiconductor device and is suitable for a single port or limited port count serial communications device.

U.S. Pat. No. 5,793,822 describes a circuit in a semiconductor device for testing jitter tolerance of a receiver in the semiconductor device. The jitter injection circuit is based on a phase locked loop frequency modulation system. The disclosed circuit is suitable for devices with a limited number of receivers. The flexibility of the circuit is limited due to its implementation as a BIST and as part of a semiconductor device. It requires a reference clock to generate the jitter.

Communications performance is generally characterized by bit error rate (BER). Most serial communications standards require a BER at or below 10⁻¹². BER is a single figure of merit for a communications system that combines the deleterious effects of low amplitude signal level, amplitude noise and timing jitter. Jitter is the perturbation of a signal in time or phase that can introduce errors and loss of synchronization.

A test for jitter implies two different goals for a transmitter and for a receiver. A transmitter is required to have a minimum of output jitter and a receiver is required to have a maximum of jitter tolerance. Methodologies for jitter testing are described in the working draft report NCITS T11.2 Project 13160DT/Rev0.0, Apr. 11, 2000 that presents three main methodologies for jitter tolerance testing of receivers. The first methodology called bit error rate testing jitter tolerance source uses a cable of known length or a filter to generate deterministic jitter (DJ) and a source of white noise to generate random jitter (RJ) and then inserts the total jitter (DJ+RJ) into the data stream. The second methodology called sinusoidal jitter tolerance measurement uses a frequency modulation technique to generate a jittery clock that is input to a data pattern generator. The jittery data output from the pattern generator is input to the receiver under test. The third methodology called direct time synthesis generates phase changes on a serial bit sequence in the time domain.

These methodologies for jitter tolerance testing of high-speed receivers may be performed only in a test laboratory with a dedicated expensive stand-alone bit error rate test set. Current automatic test equipment (ATE) used on the production floor, because of its bandwidth limitation of about 1 Gbps, does not support jitter tolerance testing using these methodologies. The speed of current communications semiconductor devices is much greater than the available speed in ATE equipment currently available.

There is thus a widely recognized need for, and it would be highly advantageous to have, a system and method for automatic production testing of jitter tolerance in multi-gigabit receivers using automatic test equipment.

### SUMMARY OF THE INVENTION

According to the present invention there is provided a method for testing a semiconductor device including a communications transmitter and a communications receiver, including: (a) providing a data signal from the communications transmitter; (b) generating a perturbation signal from test equipment; (c) combining the perturbation signal with the data signal to a combined signal thereof input to the communications receiver. Preferably, the perturbation signal and the data signal are each differential signals; and the input to the communications receiver is a differential input. Preferably, the combined signal includes jitter and a reduced voltage swing. Preferably, the method; also includes: (d) transmitting parallel data and clock from the test equipment to the communications transmitter; (e) receiving parallel data and clock from the communications receiver to the test equipment; and (f) calculating bit error rate by the test equipment.

According to the present invention there is provided a method for testing a semiconductor device including a communications transmitter and a communications receiver, including: (a) an output port of the communications transmitter for transmitting a data signal; (b) test equipment generating a perturbation signal; and (c) a combiner of the data signal and the perturbation signal thereby creating perturbed data signal to an input port of the communications receiver. Preferably, the combiner includes a resistive network and/or an impedance matching network. Preferably, the system further includes (d) a data input port of the communications transmitter receiving parallel data and clock from the test equipment wherein the data input port of the communications transmitter is operationally connected to the output port of the communications transmitter; and (e) a data output port of the communications receiver transmitting parallel data and clock to the test equipment wherein the data output port of the communications receiver is operationally connected to the input port of the communications receiver. Preferably, the data input port of the communications transmitter and the output port of the communications transmitter are connected via a serializer; and the data input port of the communications receiver and the data output port of the communications receiver are connected via a deserializer.

According to the present invention there is provided, a device for testing a transceiver that includes a transmitter and a receiver, including: (a) a mechanism for introducing parallel data and clock to the transmitter, so that the transmitter transforms the parallel data and the clock into a serial signal; (b) a mechanism for perturbing the serial signal yielding a perturbed signal; and (c) a mechanism for introducing the perturbed signal to the receiver. Preferably, the device further includes: (d) a mechanism for transforming the perturbed signal to perturbed parallel data and clock signals; and (e) a mechanism for comparing the parallel data and clock to the transmitter and the perturbed parallel data and clock signals thereby testing the transceiver.

The present invention successfully provides a method and system for testing high-speed multi-gigabit communications receivers overcoming the bandwidth limit of automatic test equipment.

### BRIEF DESCRIPTION OF THE DRAWINGS

The invention is herein described, by way of example only, with reference to the accompanying drawings, wherein:

FIG. 1 is a schematic electronic block diagram showing an embodiment of jitter tolerance production testing, according to the present invention;

FIG. 2 is a block diagram of a simplified equivalent model showing an embodiment of jitter insertion into a receiver differential input, according to the present invention;

FIG. 3 is a simplified presentation of the main signal waveforms in the jitter insertion network according to an embodiment of the present invention;

FIG. 4 is a graph of production test results for semiconductor devices, tested according to an embodiment of the present invention.

### DESCRIPTION OF THE PREFERRED EMBODIMENTS

The present invention is of a system and method for automatic production testing of jitter tolerance in multi-gigabit receivers using automatic test equipment. Specifically, the present invention can be used to perform simultaneous production testing of multiple serializer/deserializer ports on a semiconductor device.

The principles and operation of a system and method for automatic production testing of jitter tolerance in multi-gigabit receivers using automatic test equipment, according to the present invention, may be better understood with reference to the drawings and the accompanying description.

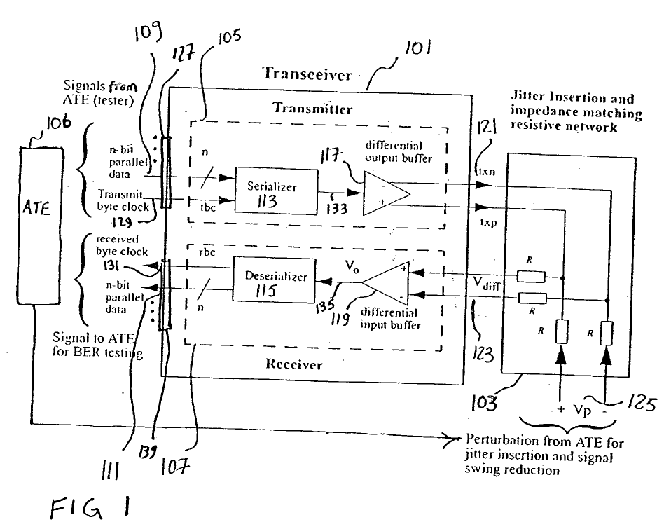

Referring now to the drawings, FIG. 1 illustrates jitter tolerance production testing, according to an embodiment of the present invention. A semiconductor device under test includes multiple transceivers 101. For simplicity, only one transceiver 101 is shown in FIG. 1. Transceiver 101 includes a transmitter 105 and a receiver 107. Parallel data of n bits 109 are input to transmitter 105 at an input port 127 by automatic test equipment (ATE) 106. A transmitter byte clock 129 is also input at input port 127 to transmitter 105 from ATE 106. A serializer 113, part of transmitter 105, converts parallel data 109 to a serial data stream 133, synchronized by clock signal 129. Serial data stream 133 is converted into a differential output serial data 121 by a differential output buffer 117, the output port of transmitter 105. Positive and negative differential outputs of differential output buffer 117 are labeled txp and txn respectively. A jitter insertion and impedance matching network 103, preferably a resistive impedance matching network is used to combine differential output serial data 121 together with a differential perturbation signal Vₚ 125 generated by ATE 106 into a combined differential signal V_{diff} 123. Differential signal 123 is input to a differential input buffer 119, input port of receiver 107 and converted to single ended serial data V₀ 135. Serial data 135 is input to a deserializer 115 and converted into n-bit parallel data 111 and a received byte clock 131. Parallel data 111 and received byte clock 131 are output from an output port 139 and input to ATE 106 for bit error testing. Using this jitter insertion technique, perturbation signal 125 can be up to the bandwidth limit of ATE 106, e.g. 1.6 gigabit/sec. The present invention offers very high jitter frequency bandwidth compared with prior art methods based on frequency modulation where the modulation bandwidth is limited to tens of megahertz. Each of multiple transceivers 101 of the semiconductor device under test are tested respectively in parallel with jitter signals generated independently by ATE 106. The jitter insertion technique of the present invention provides, therefore, in addition, a test for isolation and cross talk between transmitters 105 and receivers 107 of different transceivers 101.

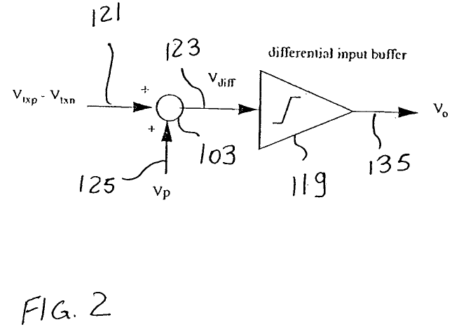

FIG. 2 illustrates a simplified model of an embodiment of the jitter insertion technique according to the present invention. Jitter insertion and impedance matching resistive network 103 is depicted as a signal combiner of differential output 121 and perturbation signal Vₚ 125. For simplicity, perturbation signal Vₚ 125 is represented as single-ended, Vₚ⁺=Vₚ and Vₚ⁻=0. Differential input buffer 119 operates on differential input V_{diff} 123 as a “sign” function; serial data output 135 Vₒ is “+” when differential input V_{diff} 123 is greater than zero, otherwise Vₒ is “−”. The following equations show the relationship between serial data output 135 Vₒ, differential input V_{diff} 123, perturbation signal Vₚ 125, and differential output signals 121 Vₜₓₚ, Vₜₓₙ.
Vₒ=sign(V_{diff}) (1)
V_{diff}=Vₜₓₚ−Vₜₓₙ+Vₚ (2)

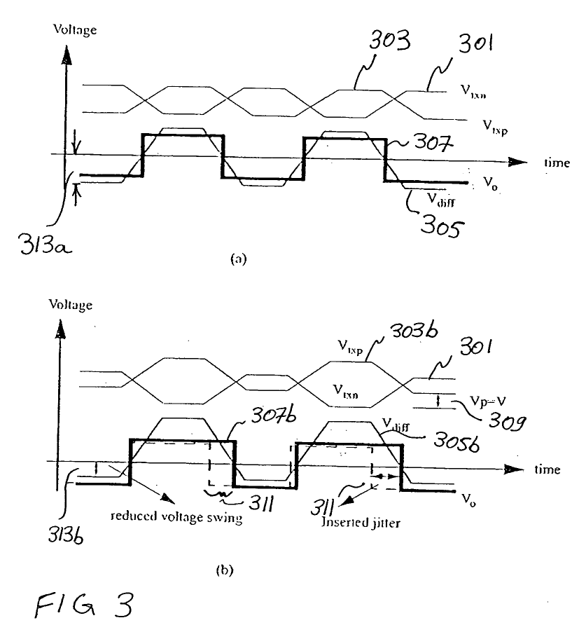

FIG. 3 illustrates main signal waveforms, according to the simplified model shown in FIG. 2. FIG. 3a illustrates the main signal waveforms when perturbation signal Vₚ 125 is zero. Differential output serial data 121 is shown by waveforms Vₜₓₚ 303 and Vₜₓₙ 301. Since Vₚ 125 is zero, differential input V_{diff} 123 is Vₜₓₚ−Vₜₓₙ as shown by waveform 305. Serial data output 135 Vₒ is shown by waveform 307.

FIG. 3b illustrates the main signal waveforms when perturbation signal Vₚ 125 is a non-zero constant V. Vₜₓₚ as shown in waveform 303b is increased by the constant V, compared with waveform 303 whereas Vₜₓₙ as shown in waveform 301 is unchanged. Differential input V_{diff} 123 is increased by constant V as shown by waveform 305b compared with waveform 305. Consequently, waveform 305b shows a reduced negative voltage swing 313b compared with a voltage swing 313a of waveform 305. Furthermore, the zero crossing locations of V_{diff} 123 shown in waveform 305b have changed compared with those of waveform 305. Hence, the locations of the edges of serial data output 135 Vₒ have changed. Therefore, serial data output 135 Vₒ, as shown by waveform 307b, includes an inserted jitter 311.

Jitter insertion network 103, according to a preferred embodiment of the present invention includes a resistive network. Differential output serial data 121 voltage as output from transmitter 105 is attenuated and its voltage swing is reduced because resistive jitter insertion network 103 acts as a voltage divider. Furthermore, perturbation signal voltage Vₚ 125 further reduces voltage swing as shown in 313a and 313b of FIG. 3. Therefore, an embodiment of the present invention also tests the receiver under a reduced voltage swing stress in addition to the jitter stress. Current industry standards require the receiver to have a high BER at very low voltage swings and with a large amount of jitter.

In general, total jitter Dj introduced into receiver 107 is a combination of jitter Tⱼ generated by transmitter 105 and jitter Nⱼ generated by jitter insertion network 103.
Dⱼ=Tⱼ+Nⱼ (3)

To a first approximation, the jitter Nⱼ generated by jitter insertion network 103 is:
Nⱼ=A*Vₚ/S (4)
where A is a constant factor dependent on resistive network 103, Vₚ is perturbation signal 125, S is the slope (volts/sec) of the rising edge of Vₜₓₚ, in waveform 303b.

Based on equation (3), inserted jitter 311 depends on characteristics, e.g. rise time, fall time, and jitter, of differential output serial data 121 from transmitter 105. In practical multi-gigabit signals, rise and fall times are about third to half the bit period. Therefore, it is possible to inject up to half a bit of jitter with a pure resistive network. If needed, an impedance network could be used to further increase the rise/fall times of the differential input voltage, V_{diff}, waveforms 305, 305b and increase the inserted jitter. Transmitter jitter Tⱼ includes both random and deterministic jitter components. The jitter insertion, according to the present invention, produces jitter beyond the requirements of current industry test standards.

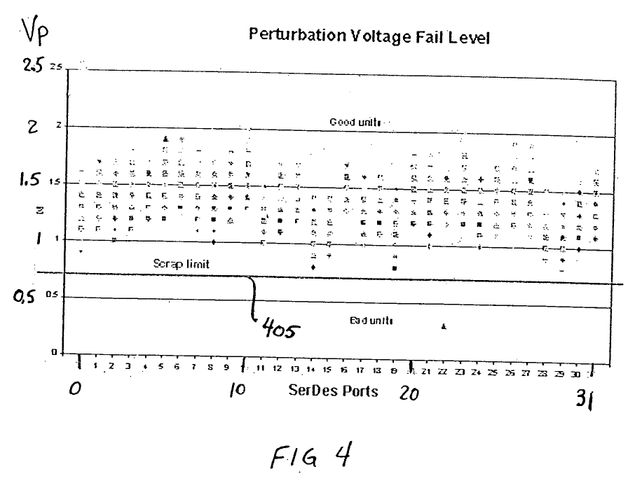

FIG. 4 is a graph of production test results for a number of Mellanox InfiniScale™ devices. Each device has 32 serializer/deserializer ports that operate at 2.5 Gbps speed. Abscissa of the graph of FIG. 4 indicates a port number of devices tested, numbered from 0 to 31. Ordinate of the graph of FIG. 4 indicates perturbation signal voltage Vₚ 125 at which a port of a device failed. Failure is defined by a bit error rate increasing to above 10⁻¹². Devices that failed at a perturbation signal voltage Vₚ 125 less than “scrap limit” 405 are rejected.

While the invention has been described with respect to a limited number of embodiments, it will be appreciated that many variations, modifications and other applications of the invention may be made.

1. A method for testing a semiconductor device including a communications transmitter and a communications receiver, comprising the steps of:
(a) providing a data signal from the communications transmitter;
(b) generating a perturbation signal from test equipment; and
(c) combining said perturbation signal with said data signal to a combined signal thereof input to the communications receiver.

2. The method, according to claim 1, wherein said perturbation signal and said data signal are each differential signals; and said input to the communications receiver is a differential input.

3. The method, according to claim 1, wherein said combined signal includes jitter.

4. The method, according to claim 1, wherein said combined signal includes a reduced voltage swing.

5. The method, according to claim 1, further comprising the steps of
(d) transmitting parallel transmitted data and clock from said test equipment to the communications transmitter wherein said transmitted data and clock upon serialization yields said data signal
(e) receiving parallel received data and clock from the communications receiver to said test equipment wherein said combined signal upon deserialization yields said received data and clock; and
(f) comparing said transmitted parallel data and clock with said received parallel data and clock to calculate a bit error rate of the device, by said test equipment.

6. A system for testing a semiconductor device including a communications transmitter and a communications receiver, comprising:
(a) an output port of the communications transmitter for transmitting a data signal;
(b) test equipment generating a perturbation signal; and
(c) a combiner of said data signal and said perturbation signal thereby creating perturbed data signal to an input port of the communications receiver.

7. The system, according to claim 6, wherein said combiner includes a resistive network.

8. The system, according to claim 6, wherein said combiner includes an impedance matching network.

9. The system, according to claim 6, further comprising:
(d) a data input port of the communications transmitter receiving parallel data and clock from said test equipment wherein said data input port of the communications transmitter is operationally connected to said output port of the communications transmitter; and
(e) a data output port of the communications receiver transmitting parallel data and clock to said test equipment wherein said data output port of the communications receiver is operationally connected to said input port of the communications receiver.

10. The system, according to claim 6, wherein said data input port of the communications transmitter and said output port of the communications transmitter are operationally connected via a serializer.

11. The system, according to claim 6, wherein said data input port of the communications receiver and said data output port of the communications receiver are operationally connected via a deserializer.

12. A device for testing a transceiver that includes a transmitter and a receiver, comprising:
(a) a mechanism for introducing parallel data and clock to the transmitter, so that the transmitter transforms said parallel data and said clock into a serial signal;
(b) a mechanism for perturbing said serial signal yielding a perturbed signal; and
(c) a mechanism for introducing said perturbed signal to the receiver.

13. The device, according to claim 12, further comprising
(d) a mechanism for transforming said perturbed signal to perturbed parallel data and clock signals; and
(e) a mechanism for comparing said parallel data and clock to the transmitter and said perturbed parallel data and clock signals thereby testing the transceiver.
